(19) United States
(12) Patent Application Publication
(10) Pub. No.: US 2025/0229636 A1
(43) Pub. Date: Jul. 17, 2025

(54) METHOD AND APPARATUS FOR DIAGNOSING BATTERY ABNORMALITY OF ECOFRIENDLY VEHICLE

(71) Applicants: Hyundai Motor Company, Seoul (KR); Kia Corporation, Seoul (KR)

(72) Inventor: Jung Hyun LEE, Yongin-si (KR)

(73) Assignees: Hyundai Motor Company, Seoul (KR); Kia Corporation, Seoul (KR)

(21) Appl. No.: 18/938,525

(22) Filed: Nov. 6, 2024

(30) Foreign Application Priority Data
Jan. 11, 2024 (KR) 10-2024-0004880

(51) Int. Cl. B60L 3/00; B60L 15/20; B60L 58/12; B60L 58/22; G01R 31/00; G01R 31/3835; H01M 10/42; H01M 10/48

(52) U.S. Cl. CPC B60L 3/0046; B60L 15/20; B60L 58/12; B60L 58/22; G01R 31/006; G01R 31/3835; H01M 10/425; H01M 10/482; H01M 10/486; B60L 2240/545; B60L 2240/547; B60L 2250/16; H01M 2010/4271; H01M 2220/20

(57) ABSTRACT

A method and apparatus for diagnosing battery abnormality of an ecofriendly vehicle may include incrementing a count value based on a cell balancing starting voltage deviation which is a voltage deviation of a plurality of cells forming a battery module of the vehicle when a cell balancing mode for adjusting the voltage deviation of the plurality of cells starts and a cell balancing ending voltage deviation which is a voltage deviation of the plurality of cells when the cell balancing mode ends, storing the count value and the identifier or the identification number of the cell having the minimum voltage among the plurality of cells, and detecting cell abnormality based on the count value and the identifier or the identification number of the cell having the minimum voltage.

### CROSS-REFERENCE TO RELATED APPLICATION

The present application claims priority to Korean Patent Application No. 10-2024-0004880 filed on Jan. 11, 2024, the entire contents of which is incorporated herein for all purposes by this reference.

### BACKGROUND OF THE PRESENT DISCLOSURE

### Field of the Present Disclosure

The present disclosure relates to a battery management system, and more particularly to a method and apparatus for diagnosing battery abnormality of an ecofriendly vehicle.

### Description of Related Art

Ecofriendly vehicles such as a hybrid electronic vehicle (HEV), a plug-in HEV, an electric vehicle (EV), etc. are provided with a battery as a storage device configured to store electrical energy to drive a motor. Such an ecofriendly vehicle is provided with a high-voltage battery different from a low-voltage battery provided in conventional internal combustion engine vehicles.

As such a high-voltage battery is configured to have higher energy density, a dangerous situation such as fire or the like may occur therein even due to a minute quality problem. For the present reason, safety of the battery becomes more important. Although a monitoring logic for battery safety is also applied to electric vehicles in mass production, prevention of generation of an accident through previous detection of battery abnormality is still insufficient.

Therefore, technology capable of preventing generation of an accident through previous detection of a battery abnormality symptom is needed.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing technology configured for previously detecting an abnormality symptom of a battery.

It is another object of the present disclosure to provide a logic configured for diagnosing a high-voltage battery by diagnosing a cell having an abnormality symptom using a cell balancing technology for balancing a voltage deviation of the high-voltage battery.

It will be appreciated by persons skilled in the art to which the present disclosure pertains that technical problems to be solved by the present disclosure are not limited to the above-described technical problems, and other technical problems will be more clearly understood from the following description.

In accordance with an aspect of the present disclosure, the above and other objects may be accomplished by the provision of a method of diagnosing battery abnormality of an ecofriendly vehicle, including incrementing a count value based on a cell balancing starting voltage deviation which is a voltage deviation of a plurality of cells forming a battery module of the vehicle when a cell balancing mode for adjusting the voltage deviation of the plurality of cells starts and a cell balancing ending voltage deviation which is a voltage deviation of the plurality of cells when the cell balancing mode ends, and storing the count value and an identifier or an identification number of a cell including a minimum voltage among the plurality of cells, and detecting cell abnormality based on the count value and the identifier or the identification number of the cell including the minimum voltage.

The detecting the cell abnormality may include detecting the cell abnormality based on whether or not the identifier or the identification number of the cell including the minimum voltage is repetitively present at different count values and whether or not a current count value is not lower than a threshold count value.

The method may further include starting the cell balancing mode, storing the cell balancing starting voltage deviation, ending the cell balancing mode based on the voltage deviation of the plurality of cells or an elapsed time, and storing the cell balancing ending voltage deviation.

The storing the count value and the identifier or the identification number of the cell having the minimum voltage among the plurality of cells may include incrementing the count value when the cell balancing ending voltage deviation is not smaller than a value obtained by summing the cell balance starting voltage deviation and a threshold voltage drop, and storing the count value and the identifier or the identification number of the cell having the minimum voltage among the plurality of cells.

The count value may be initially set to “0”, and may be incremented by “1”.

The voltage deviation of the plurality of cells may be a difference between an average voltage of the plurality of cells and the voltage of the cell having the minimum voltage amount the plurality of cells.

In the starting the cell balancing mode and the storing the cell balancing starting voltage deviation, the cell balancing mode may start when the difference between the average voltage of the plurality of cells and the voltage of the cell having the minimum voltage amount the plurality of cells is not smaller than a first threshold value.

In the ending the cell balancing mode and the storing the cell balancing ending voltage deviation, the cell balancing mode may end when a state in which the difference between the average voltage of the plurality of cells and the voltage of the cell having the minimum voltage among the plurality of cells is not greater than a second threshold value is maintained for a first threshold time period.

In the ending the cell balancing mode and the storing the cell balancing ending voltage deviation, the cell balancing mode may end when a predetermined time period elapses from a time when the cell balancing mode starts.

In the starting the cell balancing mode and the storing the cell balancing starting voltage deviation, the cell balancing starting voltage deviation may be stored when a temperature of the cell having the minimum voltage among the plurality of cells is higher than a first threshold temperature and a state of charge (SOC) value of the battery is not smaller than a first threshold rate after the cell balancing mode starts.

In the ending the cell balancing mode and the storing the cell balancing ending voltage deviation, the cell balancing ending voltage deviation may be stored when a temperature of the cell having the minimum voltage among the plurality of cells is higher than a second threshold temperature and a state of charge (SOC) value of the battery is not smaller than a second threshold rate after the cell balancing mode ends.

The method may further include transmitting a warning message to a driver and controlling the vehicle when the identifier or the identification number of the cell having the minimum voltage is repetitively present at different count values and a current count value is not lower than a threshold count value.

In accordance with another aspect of the present disclosure, there is provided an apparatus for diagnosing battery abnormality of an ecofriendly vehicle, including a battery configured to store electrical energy for driving the vehicle, the battery including a plurality of cells, a sensor unit including a voltage sensor configured to detect voltages of the plurality of cells, and a battery manager operatively connected to the sensor unit and configured to increment a count value based on a cell balancing starting voltage deviation which is a voltage deviation of the plurality of cells when a cell balancing mode for adjusting the voltage deviation of the plurality of cells starts and a cell balancing ending voltage deviation which is a voltage deviation of the plurality of cells when the cell balancing mode ends, to store the count value and an identifier or an identification number of a cell having a minimum voltage among the plurality of cells, and to detect cell abnormality based on the count value and the identifier or the identification number of the cell having the minimum voltage.

The battery manager may detect cell abnormality based on whether or not the identifier or the identification number of the cell having the minimum voltage is repetitively present at different count values and whether or not a current count value is not lower than a threshold count value.

The battery manager may start the cell balancing mode and may store the cell balancing starting voltage deviation. The battery manager may end the cell balancing mode based on the voltage deviation of the plurality of cells or an elapsed time, and may store the cell balancing ending voltage deviation.

The battery manager may increment the count value when the cell balancing ending voltage deviation is not smaller than a value obtained by summing the cell balance starting voltage deviation and a threshold voltage drop, and may store the count value and an identifier or an identification number of a cell having a minimum voltage among the plurality of cells.

The count value may be initially set to “0”, and may be incremented by “1”.

The voltage deviation of the plurality of cells may be a difference between an average voltage of the plurality of cells and the voltage of the cell having the minimum voltage amount the plurality of cells.

The battery manager may start the cell balancing mode when the difference between the average voltage of the plurality of cells and the voltage of the cell having the minimum voltage amount the plurality of cells is not smaller than a first threshold value.

The battery manager may end the cell balancing mode when a state in which the difference between the average voltage of the plurality of cells and the voltage of the cell having the minimum voltage among the plurality of cells is not greater than a second threshold value is maintained for a first threshold time period.

The battery manager may end the cell balancing mode when a predetermined time period elapses from a time when the cell balancing mode starts.

The battery manager may store the cell balancing starting voltage deviation when a temperature of the cell having the minimum voltage among the plurality of cells is higher than a first threshold temperature and a state of charge (SOC) value of the battery is not smaller than a first threshold rate after the cell balancing mode starts.

The battery manager may store the cell balancing ending voltage deviation when a temperature of the cell having the minimum voltage among the plurality of cells is higher than a second threshold temperature and a state of charge (SOC) value of the battery is not smaller than a second threshold rate after the cell balancing mode ends.

The battery manager may transmit a warning message to a driver and may be configured for controlling the vehicle when the identifier or the identification number of the cell having the minimum voltage is repetitively present at different count values and a current count value is not lower than a threshold count value.

In accordance with the above-described embodiments of the present disclosure, it may be possible to previously detect an abnormality symptom of the battery.

Furthermore, a logic configured for diagnosing a high-voltage battery by diagnosing a cell having an abnormality symptom using a cell balancing technology for balancing a voltage deviation of the high-voltage battery is provided.

Furthermore, an accident may be prevented and safety of an ecofriendly vehicle may be enhanced through an enhancement in high-voltage battery monitoring function.

Effects attainable in an exemplary embodiment of the present disclosure are not limited to the above-described effects, and other effects of the present disclosure not yet described will be more clearly understood by those skilled in the art from the following

### DETAILED DESCRIPTION

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 shows an example of a graph explaining cell balancing of a general ecofriendly vehicle;

FIG. 2 is a block diagram schematically showing a battery abnormality diagnosis apparatus according to an exemplary embodiment of the present disclosure;

FIG. 3 shows an example in which a severe voltage deviation is generated due to an abnormal cell detectable in accordance with an exemplary embodiment of the present disclosure;

FIG. 4 is a flowchart showing a method of storing a voltage deviation among cells and an SoC at a time when a cell balancing mode starts in accordance with an exemplary embodiment of the present disclosure;

FIG. 5A and FIG. 5B are flowcharts showing a method of storing a voltage deviation among cells and an SoC at a time when a cell balancing mode ends in accordance with an exemplary embodiment of the present disclosure; and

FIG. 6 is a flowchart showing a battery abnormality diagnosis method according to an exemplary embodiment of the present disclosure.

It may be understood that the appended drawings are not necessarily to scale, presenting a somewhat simplified representation of various features illustrative of the basic principles of the present disclosure. The predetermined design features of the present disclosure as included herein, including, for example, specific dimensions, orientations, locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Hereinafter, various exemplary embodiments of the present disclosure will be described in detail with reference to the accompanying drawings, and the same or similar elements are designated by the same reference numerals regardless of the numerals in the drawings and redundant description thereof will be omitted. Although “module” or “unit” is suffixed to constituent elements described in the following description, this is intended only for ease of description of the specification. The suffixes themselves have no meaning or function to distinguish the constituent element using the suffix from the constituent element using no suffix. In the following description of the exemplary embodiments of the present disclosure, a detailed description of known functions and configurations incorporated herein will be omitted when it may obscure the subject matter of the exemplary embodiments of the present disclosure. Furthermore, the exemplary embodiments of the present disclosure will be more clearly understood from the accompanying drawings and should not be limited by the accompanying drawings, and it is to be appreciated that all changes, equivalents, and substitutes that do not depart from the spirit and technical scope of the present disclosure are encompassed in an exemplary embodiment of the present disclosure.

It will be understood that, although the terms “first”, “second”, etc. may be used herein to describe various elements, these elements should not be limited by these terms. These terms are only used to distinguish one element from another.

In the case where an element is “connected” or “linked” to another element, it should be understood that the element may be directly connected or linked to the other element, or another element may be present therebetween. Conversely, in the case where an element is “directly connected” or “directly linked” to another element, it should be understood that no other element is present therebetween.

Unless clearly used otherwise, singular expressions include a plural meaning.

In the present specification, the term “comprising”, “including”, or the like, is intended to express the existence of the characteristic, the numeral, the step, the operation, the element, the part, or the combination thereof, and does not exclude another characteristic, numeral, step, operation, element, part, or any combination thereof, or any addition thereto.

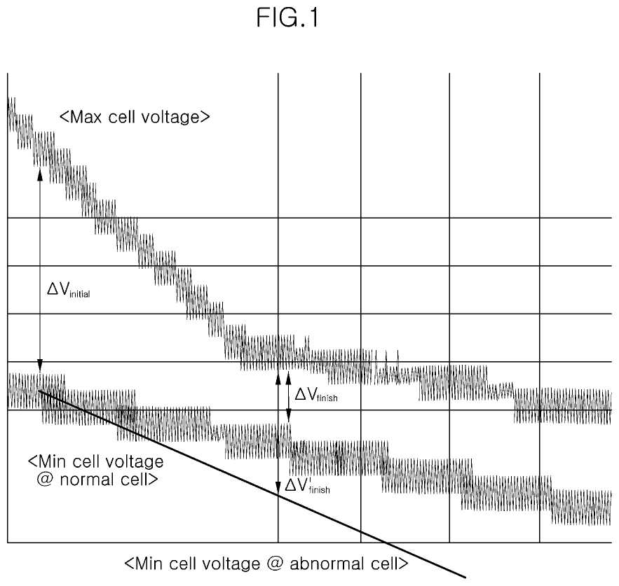

FIG. 1 shows an example of a graph explaining cell balancing of a general ecofriendly vehicle.

Cell balancing means that, when a voltage deviation between a cell having a maximum voltage and a cell having a minimum voltage among a plurality of cells is not smaller than a predetermined threshold value, the voltage deviation is controlled to be reduced through consumption of microcurrent starting from cells having higher voltages than that of the cell having the minimum voltage.

Referring to FIG. 1, a battery enters or starts a cell balancing mode for reducing a voltage deviation between a cell having a maximum voltage and a cell having a minimum voltage among a plurality of cells forming a battery module when the voltage deviation is not smaller than a predetermined threshold value for starting of the cell balancing mode.

In the instant case, the voltage deviation between the cell having the maximum voltage and the cell having the minimum voltage at a time when the cell balancing mode starts may be defined as ΔVᵢₙᵢₜᵢₐₗ.

In the cell balancing mode, current of cells having greater voltages than current of the cell having the minimum voltage is finely consumed, reducing a voltage deviation among the cells forming the battery module.

In the instant case, when the voltage deviation between the cell having the maximum voltage and the cell having the minimum voltage is not greater than a predetermined threshold value for ending of the cell balancing mode after a predetermined time period elapses in the cell balancing mode, the cell balancing mode ends.

In the instant case, the voltage deviation between the cell having the maximum voltage and the cell having the minimum voltage at a time when the cell balancing mode ends may be defined as ΔV_{finish}.

However, although the cell balancing mode ends in accordance with satisfaction of cell balancing mode ending conditions as described above, cell voltage drop caused by a micro-short circuit may be continuously generated. To check such cell voltage drop, whether or not the voltage of a cell having a minimum voltage is continuously lowered may be determined by checking whether or not the cell voltage deviation after completion of cell balancing is not smaller than a threshold value.

In the instant case, it may be possible to determine whether or not the cell voltage is continuously lowered by determining whether or not a value multiplying the cell voltage deviation at the cell balancing ending time by k (k being a constant) is not smaller than an initial cell voltage deviation, that is, ΔVᵢₙᵢₜᵢₐₗ.

That is, it may be possible to determine whether or not the voltage of the cell having the minimum voltage is continuously lowered, based on whether or not the cell voltage deviation at the cell balancing ending time satisfies conditions according to the following Expression 1.

ΔVᵢₙᵢₜᵢₐₗ≤k*ΔV_{finish} [Expression 1]

In Expression 1, ΔVᵢₙᵢₜᵢₐₗ represents a voltage deviation between a cell having a maximum voltage and a cell having a minimum voltage at a time when the cell balancing mode starts, ΔV_{finish} represents a voltage deviation between a cell having a maximum voltage and a cell having a minimum voltage at a time when the cell balancing mode ends, and k represents a constant used to determine abnormal voltage drops and can vary depending on the type of battery (e.g., NCM, LFP, and solid-state batteries).

In the instant case, “k*ΔV_{finish}” in Expression 1 may be replaced by a target cell voltage deviation value.

Even for a cell in which a serious problem has not been generated yet, generation of an internal micro-short circuit or the like may be previously diagnosed based on whether or not the conditions of Expression 1 are satisfied. Of course, even when an abnormality symptom representing progress of an internal cell short circuit is previously found, it is difficult to prevent generation of an event such as fire or the like.

Meanwhile, an identifier (ID) of the cell having the minimum voltage may be stored after completion of cell balancing.

Furthermore, when a voltage deviation between a cell having a maximum voltage and a cell having a minimum voltage among the plurality of cells forming the battery module again becomes not smaller than the predetermined threshold value for starting of the cell balancing mode, the battery may again enter or start the cell balancing mode.

In the instant case, an identifier (ID) of the cell having the minimum voltage may be stored after completion of cell balancing, similarly to the above-described case.

In the instant case, whether or not the identifier of the cell having the minimum voltage is identical to the identifier of the cell having the minimum voltage previously stored after ending of the cell balancing mode may be determined through comparison.

In the instant case, when the identifier of the cell having the minimum voltage currently stored is identical to the identifier of the cell having the minimum voltage previously stored, a voltage drop alarm is generated, and a vehicle control unit (VCU) is configured to control the vehicle to limit battery performance.

In the instant case, only in the case in which a battery temperature when the battery ends the cell balancing mode is not lower than a threshold temperature and a state of charge (SOC) value of the battery is not smaller than a threshold rate, may a voltage drop alarm be generated.

For example, only when the battery temperature is 25° C. or more and the SOC value of the battery is 30%, may a voltage drop alarm be generated.

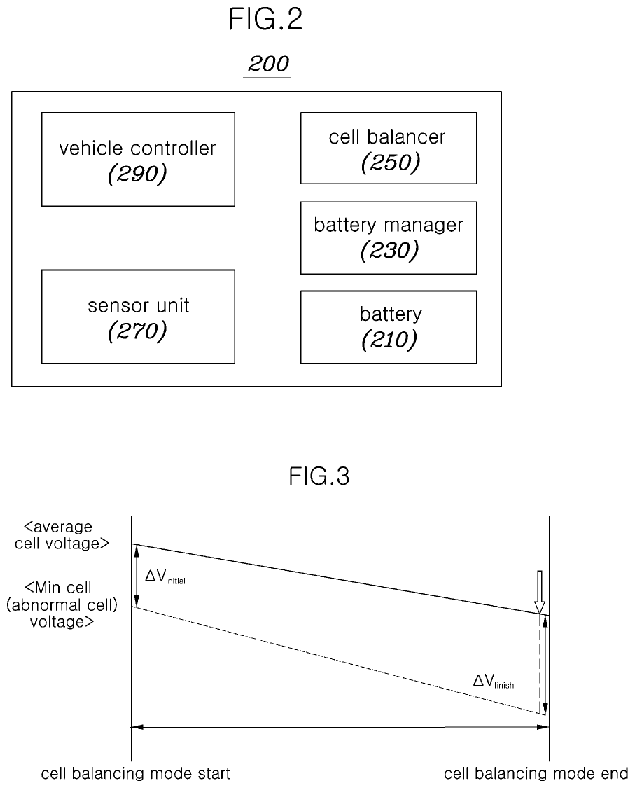

FIG. 2 is a block diagram schematically showing a battery abnormality diagnosis apparatus according to an exemplary embodiment of the present disclosure.

Referring to FIG. 2, the battery abnormality diagnosis apparatus according to the present exemplary embodiment includes a battery 210, a cell balancer 230, a battery manager 250, a sensor unit 270, and a vehicle controller 290.

The battery 210 stores electrical energy for driving the vehicle and includes a plurality of cells.

The battery manager 230 is configured to control the battery 210 to enter or start a cell balancing mode for reducing a voltage deviation among a plurality of cells forming the battery 210 when a deviation between an average voltage of the plurality of cells and a voltage of a cell having a minimum voltage among the plurality of cells in an ignition-on mode of the vehicle is not smaller than a predetermined threshold value for starting of the cell balancing mode.

In the instant case, the deviation between the average voltage of the plurality of cells and the voltage of the cell having the minimum voltage at a time when the cell balancing mode starts may be defined as ΔVᵢₙᵢₜᵢₐₗ.

The battery manager 230 may store the deviation between the average voltage of the plurality of cells and the voltage of the cell having the minimum voltage, that is, ΔVᵢₙᵢₜᵢₐₗ, and an SOC value of the battery 210 at the time when the cell balancing mode starts in a storage device such as a memory or the like.

In the instant case, the battery manager 230 may be set to store the voltage deviation ΔVᵢₙᵢₜᵢₐₗ and the SOC value of the battery 210 corresponding thereto only when the temperature of the cell having the minimum voltage exceeds a threshold temperature and the SOC value of the battery 210 is not smaller than a threshold rate.

For example, the battery manager 230 may be set to store the voltage deviation ΔVᵢₙᵢₜᵢₐₗ and the SOC value of the battery 210 corresponding thereto only when the temperature of the cell having the minimum voltage exceeds 0° C. and the SOC value of the battery 210 is not smaller than 50%.

Furthermore, the battery manager 230 ends the cell balancing mode when cell balancing is completed.

In the instant case, the battery manager 230 may end the cell balancing mode when a threshold time elapses after the cell balancing mode starts.

When a deviation among SoCs of the cells forming the battery 210 is within a threshold range (for example, 0.5% or less), the battery manager 230 may be configured to determine that cell balancing has been completed, and accordingly, may end the cell balancing mode.

Furthermore, the battery manager 230 may end the cell balancing mode when a state in which the deviation between the average voltage of the cells forming the battery 210 and the voltage of the cell having the minimum voltage is within a threshold range is maintained for a threshold time period or more than the threshold time period.

For example, the battery manager 230 may end the cell balancing mode when a state in which the deviation between the average voltage of the cells forming the battery 210 and the voltage of the cell having the minimum voltage is 5 mV or less is maintained for 10 seconds or more than 10 seconds.

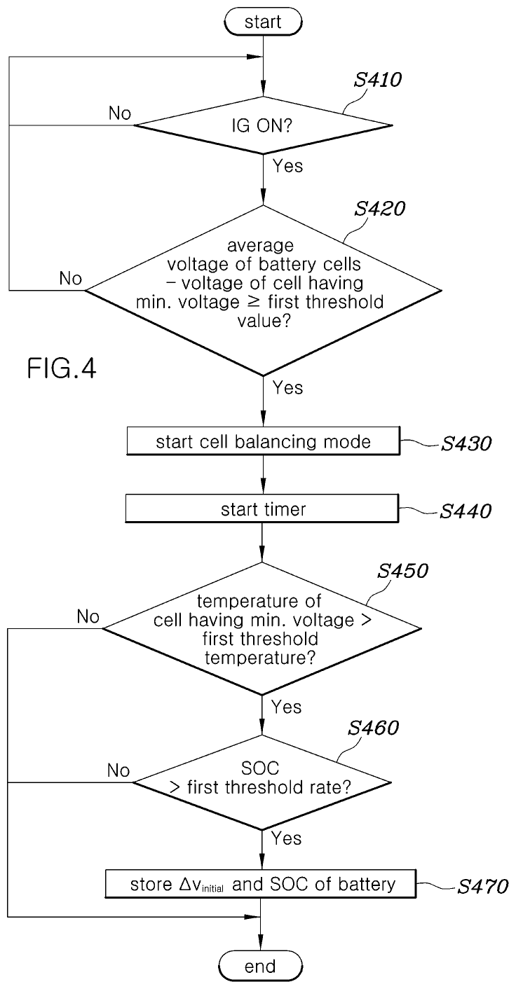

In the instant case, the deviation between the average voltage of the cells forming the battery 210 and the voltage of the cell having the minimum voltage at a time when the cell balancing mode ends may be defined as ΔV_{finish}, as shown in FIG. 3.

In the instant case, the battery manager 230 may store, in the storage device such as the memory or the like, ΔV_{finish} and an SOC value of the battery 210 corresponding thereto at a first wake-up time of a real time clock (RTC) after the vehicle enters an ignition-off mode and battery monitoring during parking is then maintained for a threshold time period or more than the threshold time period.

For example, the threshold time for continuous battery monitoring during parking may be 2 hours.

In the instant case, the battery manager 230 may store ΔV_{finish} and the SOC value of the battery 210 corresponding thereto only when the temperature of the cell having the minimum voltage exceeds a threshold temperature and the SOC value of the battery 210 is a threshold rate or more than the threshold rate.

For example, the battery manager 230 may store ΔV_{finish} and the SOC value of the battery 210 corresponding thereto only when the temperature of the cell having the minimum voltage exceeds 0° C. and the SOC value of the battery 210 is 50% or more.

When both ΔVᵢₙᵢₜᵢₐₗ and ΔV_{finish} have been stored in the storage device such as the memory or the like, the battery manager 230 may increment a battery abnormality diagnosis count value based on whether or not the voltage deviation at the time when the cell balancing mode ends satisfies conditions according to the following Expression 2.

ΔV_{finish}≥ΔVᵢₙᵢₜᵢₐₗ+Threshold Voltage Drop [Expression 2]

In Expression 2, ΔV_{finish} represents a voltage deviation between an average voltage of the battery cells and a cell having a minimum voltage the battery cells at a time when the cell balancing mode starts, ΔV_{finish} represents a voltage deviation between an average voltage of the battery cells and a cell having a minimum voltage the battery cells at a time when the cell balancing mode ends, and the threshold voltage drop represents a threshold voltage drop value for battery abnormality diagnosis counting.

In the instant case, a battery abnormality diagnosis count value when conditions according to Expression 2 are initially satisfied may become 1 from 0.

Meanwhile, the battery manager 230 stores an identifier (ID) or an identification number of the cell having the minimum voltage when the voltage deviation at the time when the cell balancing mode ends satisfies the conditions according to Expression 2.

Meanwhile, the battery manager 230 is configured to determine that abnormality has occurred in the battery 210, when the battery 210 ends the cell balancing mode after starting the cell balancing mode several times while satisfying the conditions according to Expression 2 upon ending the cell balancing mode, and, accordingly, the diagnosis count value is incremented up to a threshold number of repetition times, that is, N, and the identifier (ID) or identification number of the cell having the minimum voltage is constant at every repetition time. In the instant case, the battery manager 230 transmits a warning message to the driver and transmits information as to generation of abnormality of the battery 210 to the vehicle controller 290.

In the instant case, the warning message may be transmitted through a display screen of the vehicle or a speaker of the vehicle.

The reason why the average voltage of the plurality cells and the voltage of the cell having the minimum voltage are compared to each other, as described above, in place of comparison between the voltage of the cell having the maximum voltage and the voltage of the cell having the minimum voltage, is to prevent erroneous diagnosis because the deviation between the voltage of the cell having the maximum voltage and the voltage of the cell having the minimum voltage may be too great at different SoCs.

Furthermore, the reason why ΔVᵢₙᵢₜᵢₐₗ and ΔV_{finish} are stored only when the SOC value of the battery 210 is not smaller than a threshold rate is to prevent erroneous diagnosis occurring when an SoC difference of the battery cells is great.

Furthermore, in the case in which a difference between the SOC value of the battery 210 at the time when the cell balancing mode starts and the SOC value of the battery 210 at the time when the cell balancing mode ends is 30% or more, the battery manager 230 again monitors a voltage deviation among the cells forming the battery module of the battery 210 at a time when a difference between an SOC value of the battery 210 at a time when the vehicle enters an ignition-off mode after the battery 210 ends the cell balancing mode and the SOC value of the battery 210 at the time when the battery 210 enters the cell balancing mode becomes lower than 30%.

When the battery 210 enters the cell balancing mode by the battery manager 230, the cell balancer 250 finely consumes current of cells having higher voltages than that of the cell having the minimum voltage, reducing a voltage deviation among the cells.

The sensor unit 270 measures a voltage or temperature of the battery 210.

In the instant case, although not shown, the sensor unit 270 may include at least one voltage sensor and/or at least one temperature sensor.

The sensor unit 270 may measure voltage variations of all of the battery cells forming the battery 210.

The vehicle controller 290 is configured to control the vehicle based on an output of the battery 210.

In the instant case, the vehicle controller 290 receives information as to generation of abnormality of the battery 210 from the battery manager 230, and is configured to control the vehicle based on the received information.

For example, upon receiving information as to generation of abnormality of the battery 210 from the battery manager 230, the vehicle controller 290 may gradually decrease the speed of the vehicle or may be configured for controlling the vehicle to escape to a safe area.

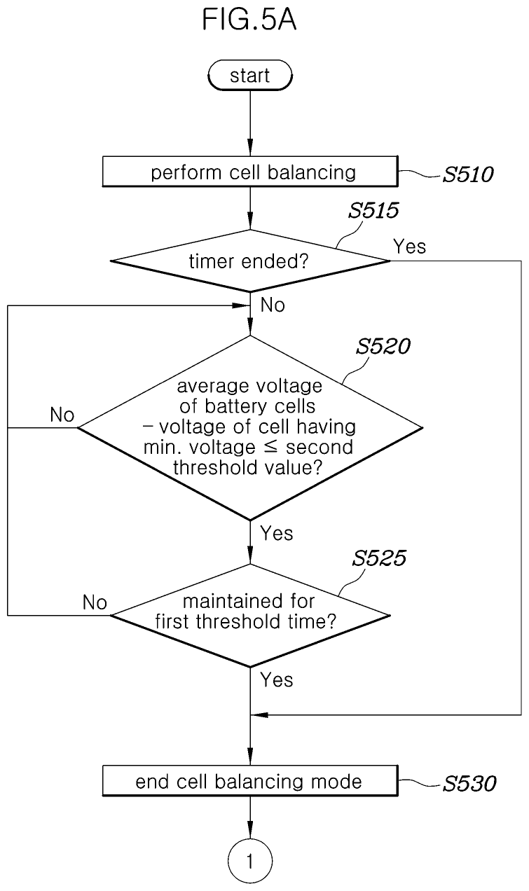

FIG. 4 is a flowchart showing a method of storing a voltage deviation among cells and an SoC at a time when a cell balancing mode starts in accordance with an exemplary embodiment of the present disclosure.

The method of storing a voltage deviation among cells and an SoC at a time when a cell balancing mode starts in accordance with an exemplary embodiment of the present disclosure may be performed by the battery manager 230 of the battery abnormality diagnosis apparatus 200 of FIG. 2.

In an exemplary embodiment of the present disclosure, each of the cell balancer 230, the battery manager 250 and the vehicle controller 290 may be implemented by a processor in a form of hardware or software, or in a combination of hardware and software. Alternatively, the cell balancer 230, the battery manager 250 and the vehicle controller 290 may be implemented by a processor may be implemented as a single processor in a form of hardware or software, or in a combination of hardware and software.

Referring to FIG. 4, the battery manager 230 is configured to determine whether or not the vehicle is in an ignition-on state (S410). When the vehicle is in the ignition-on state, the battery manager 230 is configured to determine whether or not a difference between an average voltage of a plurality of cells forming a battery module of the vehicle and a cell having a minimum voltage among the plurality of cells is not smaller than a first threshold value (S420).

When the difference between the average voltage of the plurality of cells and the cell having the minimum voltage is not smaller than the first threshold value, based on results of determination of step S420, the battery manager 230 starts a cell balancing mode (S430), and starts a timer (S440).

On the other hand, when the difference between the average voltage of the plurality of cells and the cell having the minimum voltage is smaller than the first threshold value, based on results of determination of step S420, the battery manager 230 again executes step S410 of determining whether or not the vehicle is in the ignition-on state.

Furthermore, the battery manager 230 is configured to determine whether or not a temperature of the cell having the minimum voltage is higher than a first threshold temperature (S450). When the temperature of the cell having the minimum voltage is higher than the first threshold temperature, the battery manager 230 is configured to determine whether or not a state of charge (SOC) value of the battery 210 is greater than a first threshold rate (S460).

When the SOC value of the battery 210 is greater than the first threshold rate, based on results of determination of step S460, the battery manage 230 stores a cell balancing ending voltage deviation corresponding to a difference between the average voltage of the plurality of cells and the cell having the minimum voltage and the SOC value of the battery 210 upon starting of the cell balancing mode (S470).

S450 and S460 operations in FIG. 4 may be performed sequentially, but is not necessarily sequentially performed but the order of operations may be changed to S460 and S450.

In the instant case, the cell balance starting voltage deviation and the SOC value of the battery 210 may be stored in a storage device such as a memory or the like connected to the battery manager 230 or internally provided in the battery manager 230.

On the other hand, when the temperature of the cell having the minimum voltage is not higher than the first threshold temperature, based on results of determination of step S450, or the SOC value of the battery 210 is not greater than the first threshold rate, based on results of determination of step S460, the battery manager 230 ends a control procedure without storing the cell balance starting voltage deviation and the SOC value of the battery 210.

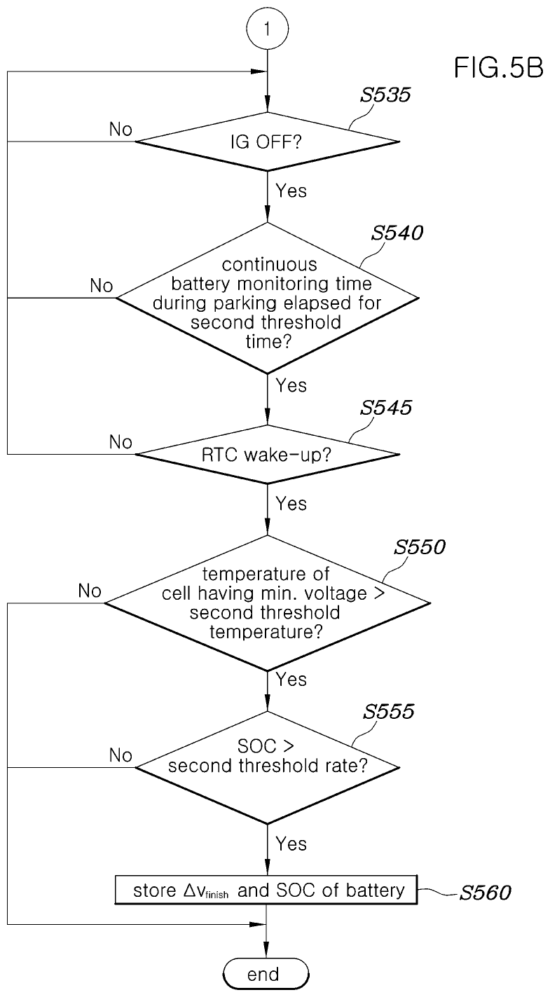

FIG. 5A and FIG. 5B are flowcharts showing a method of storing a voltage deviation among cells and an SoC at a time when a cell balancing mode ends in accordance with an exemplary embodiment of the present disclosure.

The method of storing a voltage deviation among cells and an SoC at a time when a cell balancing mode ends in accordance with an exemplary embodiment of the present disclosure may be performed by the battery manager 230 of the battery abnormality diagnosis apparatus 200 of FIG. 2.

Referring to FIG. 5A and FIG. 5B, the battery manager 230 is configured to perform cell balancing by controlling the cell balancer 250 (S510).

In the instant case, the battery manager 230 may perform cell balancing by controlling a plurality of battery cells forming a battery module to consume microcurrent starting from cells having higher voltages than that of a cell having a minimum voltage.

Furthermore, the battery manager 230 is configured to determine whether or not a timer set upon starting of a cell balancing mode has ended (S515). When the timer has ended, the battery manager 230 ends the cell balancing mode (S530).

When the timer has not ended yet, based on results of determination of step S515, the battery manager 230 is configured to determine whether or not a difference between an average voltage of the plurality of cells forming the battery 210 and a voltage of a cell having a minimum voltage among the plurality of cells is not greater than a second threshold value (S520).

When the difference between the average voltage of the plurality of cells forming the battery 210 and the voltage of the cell having the minimum voltage is not greater than the second threshold value, based on results of determination of step S520, the battery manager 230 is configured to determine whether or not a period in which the voltage difference is not greater than the second threshold value is maintained for a first threshold time (S525). When the period in which the voltage difference is not greater than the second threshold value is maintained for the first threshold time, the battery manager 230 ends the cell balancing mode (S530).

In the instant case, the first threshold time may be set to a predetermined value in accordance with user setting. For example, the first threshold time may be set to 10 seconds.

Furthermore, the battery manager 230 is configured to determine whether or not the vehicle is in an ignition-off state (S535). When the vehicle is in the ignition-off state, the battery manager 230 is configured to determine whether or not a continuous battery monitoring time during parking has elapsed not to be smaller than a second threshold time (S540).

When the continuous battery monitoring time during parking has elapsed not to be smaller than the second threshold time, based on results of determination of step S540, the battery manager 230 is configured to determine whether or not a real time clock (RTC) is in a wake-up state (S545). When the RTC is in the wake-up state, the battery manager 230 is configured to determine whether or not a temperature of the cell having the minimum voltage is greater than a second threshold temperature (S550). When the temperature of the cell having the minimum voltage is greater than the second threshold temperature, the battery manager 230 is configured to determine whether or not a state of charge (SOC) value of the battery 210 is greater than a second threshold rate (S555).

When the SOC value of the battery 210 is greater than the second threshold rate, based on results of determination of step S555, the battery manager 230 stores a cell balancing ending voltage deviation corresponding to the voltage deviation between an average voltage of the battery cells and a voltage of the cell having the minimum voltage upon ending of the cell balancing mode and the SOC value of the battery 210 (S560).

In the instant case, the cell balancing ending voltage deviation and the SOC value of the battery 210 may be stored in a storage device such as a memory or the like connected to the battery manager 230 or internally provided in the battery manager 230.

On the other hand, when the temperature of the cell having the minimum voltage is not higher than the second threshold temperature, based on results of determination of step S550, or the SOC value of the battery 210 is not greater than the second threshold rate, based on results of determination of step S555, the battery manager 230 ends a control procedure without storing the cell balancing ending voltage deviation and the SOC value of the battery 210.

S550 and S555 operations in FIG. 5B may be performed sequentially, but is not necessarily sequentially performed but the order of operations may be changed to S555 and S550.

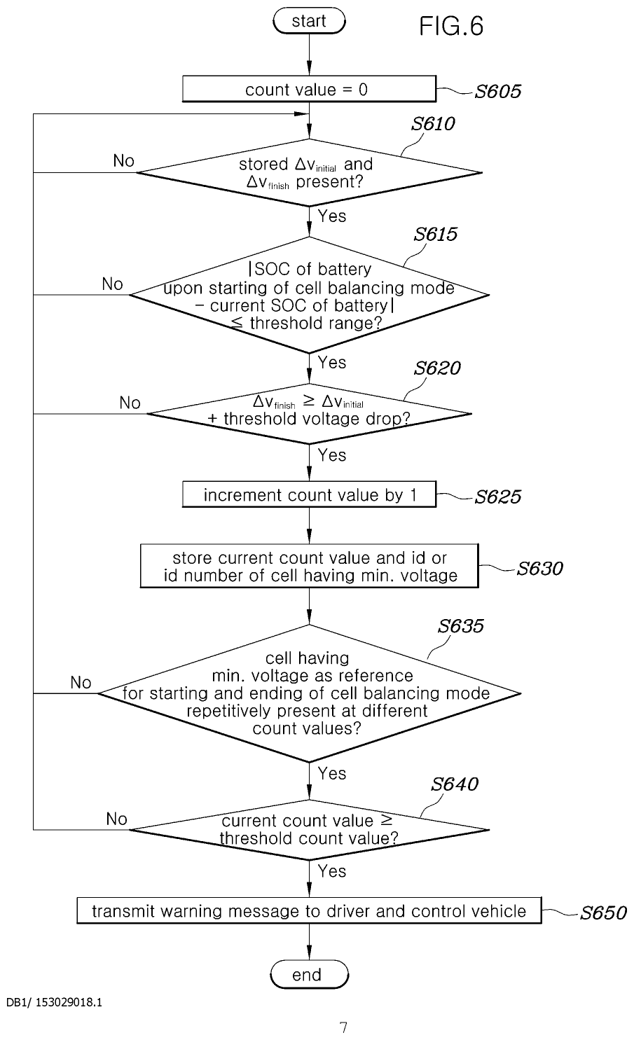

FIG. 6 is a flowchart showing a battery abnormality diagnosis method according to an exemplary embodiment of the present disclosure.

The battery abnormality diagnosis method according to the exemplary embodiment of the present disclosure may be performed by the battery manager 230 of the battery abnormality diagnosis apparatus of FIG. 2.

Referring to FIG. 6, the battery manager 230 sets an initial value of a counter for battery abnormality diagnosis to 0 (S605), and then is configured to determine whether or not a cell balance starting voltage deviation and a cell balancing ending voltage deviation corresponding to a current count value have been stored in a memory of the battery manager 230 or a memory linked to the battery manager 230 (S610).

When there are a cell balance starting voltage deviation and a cell balancing ending voltage deviation corresponding to the current count value, based on results of determination of step S610, the battery manager 230 is configured to determine whether or not an absolute value of a difference between an SOC value of the battery upon starting of the cell balancing mode and a current SOC value of the battery is not greater than a threshold range (S615).

In the instant case, the threshold range may be set to various values in accordance with user setting, and may be set to, for example, 30%.

When the absolute value of the difference between the SOC value of the battery upon entrance to the cell balancing mode and the current SOC value of the battery is not greater than the threshold range, the battery manager 230 is configured to determine whether or not the cell balancing ending voltage deviation is not smaller than a value obtained by summing the cell balance starting voltage deviation and a threshold voltage drop (S620).

When the cell balancing ending voltage deviation is not smaller than the value obtained by summing the cell balance starting voltage deviation and the threshold voltage drop, based on results of determination of step S620, the battery manager 230 increments a count value (S625), and then stores the count value and an identifier or an identification number of a cell having a minimum voltage among the plurality of cells (S630).

Furthermore, the battery manager 230 is configured to determine whether or not a cell having a minimum voltage, which is a reference for starting and ending of the cell balancing mode, is repetitively present at different count values (S635). When the cell having the minimum voltage is repetitively present, the battery manager 230 is configured to determine whether or not the current count value is not lower than a threshold count value (S640).

When the current count value is not lower than the threshold count value, based on results of determination of step S640, the battery manager 230 transmits a warning message as to battery abnormality to the driver, and is configured to control the vehicle (S650).

In the instant case, the warning message may be transmitted through a display screen of the vehicle or a speaker of the vehicle.

In the instant case, the battery manager 230 may be configured for controlling the vehicle by transmitting information as to generation of battery abnormality to the vehicle controller 290.

For example, upon receiving information as to generation of abnormality of the battery 210 from the battery manager 230, the vehicle controller 290 may gradually decrease the speed of the vehicle or may be configured for controlling the vehicle to escape to a safe area.

In accordance with the exemplary embodiments of the present disclosure described heretofore, it may be possible to previously detect an abnormality symptom of the battery.

Furthermore, a logic configured for diagnosing a high-voltage battery by diagnosing a cell having an abnormality symptom using a cell balancing technology for balancing a voltage deviation of the high-voltage battery is provided.

Furthermore, an accident may be prevented and safety of an ecofriendly vehicle may be enhanced through an enhancement in high-voltage battery monitoring function.

Furthermore, the term related to a control device such as “controller”, “control apparatus”, “control unit”, “control device”, “control module”, or “server”, etc refers to a hardware device including a memory and a processor configured to execute one or more steps interpreted as an algorithm structure. The memory stores algorithm steps, and the processor executes the algorithm steps to perform one or more processes of a method in accordance with various exemplary embodiments of the present disclosure. The control device according to exemplary embodiments of the present disclosure may be implemented through a nonvolatile memory configured to store algorithms for controlling operation of various components of a vehicle or data about software commands for executing the algorithms, and a processor configured to perform operation to be described above using the data stored in the memory. The memory and the processor may be individual chips. Alternatively, the memory and the processor may be integrated in a single chip. The processor may be implemented as one or more processors. The processor may include various logic circuits and operation circuits, may be configured for processing data according to a program provided from the memory, and may be configured to generate a control signal according to the processing result.

The control device may be at least one microprocessor operated by a predetermined program which may include a series of commands for carrying out the method included in the aforementioned various exemplary embodiments of the present disclosure.

The aforementioned invention can also be embodied as computer readable codes on a computer readable recording medium. The computer readable recording medium is any data storage device that can store data which may be thereafter read by a computer system and store and execute program instructions which may be thereafter read by a computer system. Examples of the computer readable recording medium include Hard Disk Drive (HDD), solid state disk (SSD), silicon disk drive (SDD), read-only memory (ROM), random-access memory (RAM), CD-ROMs, magnetic tapes, floppy discs, optical data storage devices, etc and implementation as carrier waves (e.g., transmission over the Internet). Examples of the program instruction include machine language code such as those generated by a compiler, as well as high-level language code which may be executed by a computer using an interpreter or the like.

In various exemplary embodiments of the present disclosure, each operation described above may be performed by a control device, and the control device may be configured by a plurality of control devices, or an integrated single control device.

In various exemplary embodiments of the present disclosure, the memory and the processor may be provided as one chip, or provided as separate chips.

In various exemplary embodiments of the present disclosure, the scope of the present disclosure includes software or machine-executable commands (e.g., an operating system, an application, firmware, a program, etc.) for enabling operations according to the methods of various embodiments to be executed on an apparatus or a computer, a non-transitory computer-readable medium including such software or commands stored thereon and executable on the apparatus or the computer.

In various exemplary embodiments of the present disclosure, the control device may be implemented in a form of hardware or software, or may be implemented in a combination of hardware and software.

Furthermore, the terms such as “unit”, “module”, etc. included in the specification mean units for processing at least one function or operation, which may be implemented by hardware, software, or a combination thereof.

In an exemplary embodiment of the present disclosure, the vehicle may be referred to as being based on a concept including various means of transportation. In some cases, the vehicle may be interpreted as being based on a concept including not only various means of land transportation, such as cars, motorcycles, trucks, and buses, that drive on roads but also various means of transportation such as airplanes, drones, ships, etc.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the present specification, unless stated otherwise, a singular expression includes a plural expression unless the context clearly indicates otherwise.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

According to an exemplary embodiment of the present disclosure, components may be combined with each other to be implemented as one, or some components may be omitted.

Hereinafter, the fact that pieces of hardware are coupled operably may include the fact that a direct and/or indirect connection between the pieces of hardware is established by wired and/or wirelessly.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A method of diagnosing battery abnormality of a vehicle, the method comprising:
incrementing, by a processor, a count value based on a cell balancing starting voltage deviation which is a voltage deviation of a plurality of cells forming a battery module of the vehicle when a cell balancing mode for adjusting the voltage deviation of the plurality of cells starts and a cell balancing ending voltage deviation which is the voltage deviation of the plurality of cells when the cell balancing mode ends, and storing the count value and an identifier or an identification number of a cell having a minimum voltage among the plurality of cells; and
detecting, by the processor, cell abnormality based on the count value and the identifier or the identification number of the cell having the minimum voltage.

2. The method of claim 1, wherein the detecting the cell abnormality includes detecting the cell abnormality based on whether or not the identifier or the identification number of the cell having the minimum voltage is repetitively present at different count values and whether or not a current count value is not lower than a threshold count value.

3. The method of claim 1, further including:
starting, by the processor, the cell balancing mode and storing, by the processor, the cell balancing starting voltage deviation; and
ending, by the processor, the cell balancing mode based on the voltage deviation of the plurality of cells or an elapsed time, and storing the cell balancing ending voltage deviation.

4. The method of claim 1, wherein the storing the count value and the identifier or the identification number of the cell having the minimum voltage among the plurality of cells includes:
incrementing the count value in response that the cell balancing ending voltage deviation is not smaller than a value obtained by summing the cell balance starting voltage deviation and a threshold voltage drop; and
storing the count value and the identifier or the identification number of the cell having the minimum voltage among the plurality of cells.

5. The method of claim 1, wherein the count value is initially set to “0”, and is incremented by “1”.

6. The method of claim 3, wherein the voltage deviation of the plurality of cells is a difference between an average voltage of the plurality of cells and the voltage of the cell having the minimum voltage amount the plurality of cells.

7. The method of claim 6, wherein, in the starting the cell balancing mode and the storing the cell balancing starting voltage deviation, the cell balancing mode starts in response that the difference between the average voltage of the plurality of cells and the voltage of the cell having the minimum voltage amount the plurality of cells is not smaller than a first threshold value.

8. The method of claim 6, wherein, in the ending the cell balancing mode and the storing the cell balancing ending voltage deviation, the cell balancing mode ends in response that a state in which the difference between the average voltage of the plurality of cells and the voltage of the cell having the minimum voltage among the plurality of cells is not greater than a second threshold value is maintained for a first threshold time period.

9. The method of claim 1, wherein, in the ending the cell balancing mode and the storing the cell balancing ending voltage deviation, the cell balancing mode ends in response that a predetermined time period elapses from a time when the cell balancing mode starts.

10. The method of claim 1, wherein, in the starting the cell balancing mode and the storing the cell balancing starting voltage deviation, the cell balancing starting voltage deviation is stored in response that a temperature of the cell having the minimum voltage among the plurality of cells is higher than a first threshold temperature and a state of charge (SOC) value of the battery is not smaller than a first threshold rate after the cell balancing mode starts.

11. The method of claim 1, wherein, in the ending the cell balancing mode and the storing the cell balancing ending voltage deviation, the cell balancing ending voltage deviation is stored in response that a temperature of the cell having the minimum voltage among the plurality of cells is higher than a second threshold temperature and a state of charge (SOC) value of the battery is not smaller than a second threshold rate after the cell balancing mode ends.

12. The method of claim 1, further including:
transmitting, by the processor, a warning message to a driver and controlling the vehicle in response that the identifier or the identification number of the cell having the minimum voltage is repetitively present at different count values and a current count value is not lower than a threshold count value.

13. The method of claim 1, further including:
upon concluding that the cell abnormality is generated, the processor is configured to decrease a speed of the vehicle.

14. An apparatus for diagnosing battery abnormality of a vehicle, comprising:
a battery configured to store electrical energy for driving the vehicle, the battery including a plurality of cells;
a sensor unit including a voltage sensor configured to detect voltages of the plurality of cells; and
a battery manager operatively connected to the sensor unit and configured to increment a count value based on a cell balancing starting voltage deviation which is a voltage deviation of the plurality of cells when a cell balancing mode for adjusting the voltage deviation of the plurality of cells starts and a cell balancing ending voltage deviation which is the voltage deviation of the plurality of cells when the cell balancing mode ends, to store the count value and an identifier or an identification number of a cell having a minimum voltage among the plurality of cells, and to detect cell abnormality based on the count value and the identifier or the identification number of the cell having the minimum voltage.

15. The apparatus of claim 14, wherein the battery manager is configured to detect the cell abnormality based on whether or not the identifier or the identification number of the cell having the minimum voltage is repetitively present at different count values and whether or not a current count value is not lower than a threshold count value.

16. The apparatus of claim 14,
wherein the battery manager starts the cell balancing mode and stores the cell balancing starting voltage deviation; and
wherein the battery manager ends the cell balancing mode based on the voltage deviation of the plurality of cells or an elapsed time, and stores the cell balancing ending voltage deviation.

17. The apparatus of claim 14, wherein the battery manager increments the count value in response that the cell balancing ending voltage deviation is not smaller than a value obtained by summing the cell balance starting voltage deviation and a threshold voltage drop, and stores the count value and the identifier or the identification number of the cell having the minimum voltage among the plurality of cells.

18. The apparatus of claim 14, wherein the count value is initially set to “0”, and is incremented by “1”.

19. The apparatus of claim 14, wherein the voltage deviation of the plurality of cells is a difference between an average voltage of the plurality of cells and the voltage of the cell having the minimum voltage amount the plurality of cells.

20. The apparatus of claim 18, wherein the battery manager starts the cell balancing mode in response that the difference between the average voltage of the plurality of cells and the voltage of the cell having the minimum voltage amount the plurality of cells is not smaller than a first threshold value.

21. The apparatus of claim 18, wherein the battery manager ends the cell balancing mode in response that a state in which the difference between the average voltage of the plurality of cells and the voltage of the cell having the minimum voltage among the plurality of cells is not greater than a second threshold value is maintained for a first threshold time period.

22. The apparatus of claim 14, wherein the battery manager ends the cell balancing mode in response that a predetermined time period elapses from a time when the cell balancing mode starts.

23. The apparatus of claim 14, wherein the battery manager stores the cell balancing starting voltage deviation in response that a temperature of the cell having the minimum voltage among the plurality of cells is higher than a first threshold temperature and a state of charge (SOC) value of the battery is not smaller than a first threshold rate after the cell balancing mode starts.

24. The apparatus of claim 14, wherein the battery manager stores the cell balancing ending voltage deviation in response that a temperature of the cell having the minimum voltage among the plurality of cells is higher than a second threshold temperature and a state of charge (SOC) value of the battery is not smaller than a second threshold rate after the cell balancing mode ends.

25. The apparatus of claim 14, wherein the battery manager transmits a warning message to a driver and is configured to control the vehicle in response that the identifier or the identification number of the cell having the minimum voltage is repetitively present at different count values and a current count value is not lower than a threshold count value.

26. The apparatus of claim 14, further including:
a vehicle controller operatively connected to the battery manager,
wherein in response that the battery manager concludes that the cell abnormality is generated, the vehicle controller is configured to decrease a speed of the vehicle.
